(19) United States
(12) Patent Application Publication
(10) Pub. No.: US 2026/0075731 A1
(43) Pub. Date: Mar. 12, 2026

(54) SOUND CARD

(71) Applicant: GUANGDONG DINGCHUANG SMART MANUFACTURING CO.,LTD., DONGGUAN (CN)

(72) Inventors: JUN LU, DONGGUAN (CN); MINGZHANG LUO, DONGGUAN (CN); PINGPING LIAO, DONGGUAN (CN)

(21) Appl. No.: 19/362,590

(22) Filed: Oct. 20, 2025

Related U.S. Application Data
(63) Continuation-in-part of application No. 18/945,821, filed on Nov. 13, 2024, now Pat. No. 12,468,503.

(30) Foreign Application Priority Data
Sep. 7, 2024 (CN) 202411254962.X
Sep. 7, 2024 (CN) 202422199606.4
Oct. 11, 2025 (CN) 202522157473.9
Oct. 11, 2025 (CN) 202522158099.4
Oct. 11, 2025 (CN) 202522158591.1

(51) Int. Cl. H05K 5/02; F21V 23/00; F21V 33/00; F21Y 115/10; H05K 5/00

(52) U.S. Cl. CPC H05K 5/0221; F21V 23/008; F21V 33/0056; H05K 5/0069; H05K 5/0247; F21Y 2115/10

(57) ABSTRACT

A sound card includes a shell, a control assembly, and a light emitting assembly. The shell is provided with an accommodating chamber. The control assembly includes a first circuit board arranged in the accommodating chamber, and a plurality of function keys. The light emitting assembly arranged in the accommodating chamber and electrically connected to the first circuit board. The light emitting assembly is configured to emit light. The function keys are configured for controlling and adjusting the sound card, light emitted by the lighting emitting assembly illuminates the function keys including the outer surfaces thereof exposed to outside of the shell. By using the light emitting assembly to transmit light from the inside of the shell to the outside of the shell, the buttons have the light transmittance effect, allowing users to enjoy auditory effects while combining visual effects to create a more three-dimensional atmosphere.

### CROSS-REFERENCE TO RELATED APPLICATIONS

The application is a continuation-in-part of U.S. Ser. No. 18/945821, now pending, entitled SOUND CARD, filed on Nov. 13, 2024, and the application claims priorities of Chinese Patent Application No. 2025221574739, filed on Oct. 11, 2025, Chinese Patent Application No. 2025221580994, filed on Oct. 11, 2025, and Chinese Patent Application No. 2025221585911, filed on Oct. 11, 2025, the entire contents of which are incorporated herein by reference.

### TECHNICAL FIELD

The present disclosure relates to the technical field of external sound card structures, and in particular, to a sound card.

### BACKGROUND

A sound card, also known as an audio card or sound effect card, is the most basic component of a computer multimedia system. It is a hardware that achieves mutual conversion of sound waves/digital signals. A basic function of the sound card is to convert original sound signals from a microphone, a tape, a compact disc, and the like, and output the signals to a sound device such as a earphone, a speaker, a loudspeaker, and a recorder, or to produce sounds of a synthetic instrument through a Musical Instrument Digital Interface (MIDI).

An external sound card is an audio jack device that is connected to a computer or a mobile device through a USB jack. It has the advantages of easy use and mobility, and is particularly suitable for environments that require better sound quality, such as connecting a laptop. The external sound card can provide richer jacks and higher sound quality, support various platform systems such as Windows, Mac, and iOS, and provide various jacks to meet different recording needs.

However, the existing external sound card has a single style and only provides the basic function, so that a user only has acoustic enjoyment during use, but there is no strong visual effect.

### SUMMARY

A sound card, configured to be connected to an external device to achieve mutual conversion of sound waves/digital signals, wherein the sound card comprises a shell, provided with an accommodating chamber; a light emitting assembly arranged in the accommodating chamber, and configured to emit light; and a control assembly. The control assembly comprises a first circuit board and a plurality of function keys, the first circuit board is arranged in the accommodating chamber, the plurality of function keys are mounted in the shell with outer surfaces of the function keys exposed to outside of the shell, the function keys and the lighting assembly are electrically connected to the first circuit board, and the function keys are configured for controlling or adjusting the sound card, light emitted by the lighting emitting assembly illuminates the function keys including the outer surfaces thereof exposed to outside of the shell.

Compared with the sound card in the prior art, which has the technical problems of single style and inability of achieving a strong visual effect, the sound card provided in present application using the light emitting assembly to transmit light from the inside of the shell to the outside of the shell, the buttons have the light transmittance effect, allowing users to enjoy auditory effects while combining visual effects to create a more three-dimensional atmosphere.

### BRIEF DESCRIPTION OF THE DRAWINGS

In order to explain the technical solutions of the embodiments of the present disclosure more clearly, the following will briefly introduce the accompanying drawings used in the embodiments. Apparently, the drawings in the following description are only some embodiments of the present disclosure. Those of ordinary skill in the art can obtain other drawings based on these drawings without creative work.

FIG. 1 is a three-dimensional view of a sound card according to a first embodiment of the present disclosure;

FIG. 2 is a three-dimensional view of a sound card in another angle according to a first embodiment of the present disclosure;

FIG. 3 is an exploded view of a sound card according to a first embodiment of the present disclosure;

FIG. 4 is an exploded view of a sound card in another angle according to a first embodiment of the present disclosure;

FIG. 5 is a cross-sectional view of the sound card shown in FIG. 1 along line V-V;

FIG. 6 is an enlarged view of part A of the sound card shown in FIG. 5;

FIG. 7 is a cross-sectional view of the sound card shown in FIG. 1 along line VII-VII;

FIG. 8 is an enlarged view of part B of the sound card in FIG. 7;

FIG. 9 is a three-dimensional view of a first light guide member of the sound card shown in FIG. 1;

FIG. 10 is an enlarged view of part C of the first light guide member shown in FIG. 9; and

FIG. 11 is a schematic view of a control region on a surface shell of the sound card shown in FIG. 1.

FIG. 12 is a schematic three-dimensional view of a sound card according to a second embodiment of the present disclosure.

FIG. 13 is an exploded view of a sound card according to a second embodiment of the present disclosure.

FIG. 14 is another schematic three-dimensional view of a sound card according to a second embodiment of the present disclosure.

FIG. 15 is a schematic view of the trigger cover according to a second embodiment of the present disclosure.

FIG. 16 shows an opposite view of the trigger cover of FIG. 15.

FIG. 17 is a cross sectional view along Y axis direction of FIG. 15.

FIG. 18 is an exploded view of a shielding cover and a second circuit board according to a second embodiment of the present disclosure.

FIG. 19 is a schematic view of the shielding cover according to a second embodiment of the present disclosure.

FIG. 20 is a voltage division circuit diagram of a second analog interface according to the second embodiment of the application.

### DETAILED DESCRIPTION OF THE EMBODIMENTS

In order to facilitate understanding the present disclosure, the present disclosure will be described more comprehensively below with reference to related accompanying drawings. Preferred implementations of the present disclosure are provided in the drawings. However, the present disclosure can be implemented in many different forms, and are not limited to the implementations described herein. On the contrary, these implementations are provided to make the content disclosed in the present disclosure understood more thoroughly and comprehensively.

It should be noted that when an element is referred to as being “fixed to” another element, the element can be directly on another component or there can be a centered element. When an element is considered to be “connected” to another element, the element can be directly connected to another element or there may be a centered element. The terms “inner”, “outer”, “left”, “right”, and similar expressions used herein are for illustrative purposes only and do not necessarily represent the only implementation.

Unless otherwise defined, all technical and scientific terms used herein have the same meaning as those commonly understood by a person skilled in the art to which the present disclosure belongs. Terms used in the specification of the present disclosure herein are merely intended to describe objectives of the specific embodiments, but are not intended to limit the present disclosure. The term “and/or” used herein includes any and all combinations of one or more related listed items.

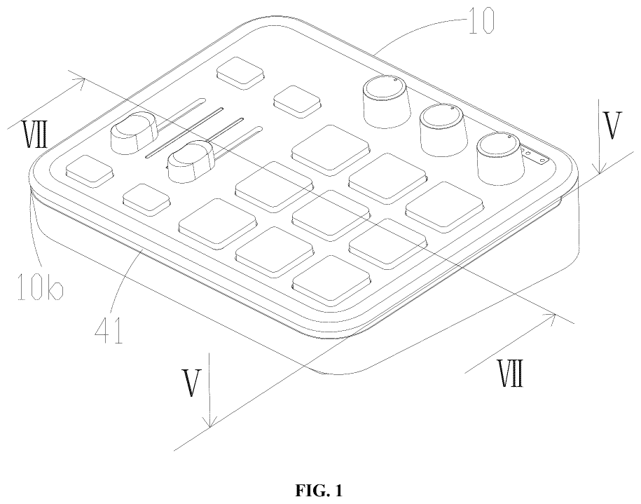

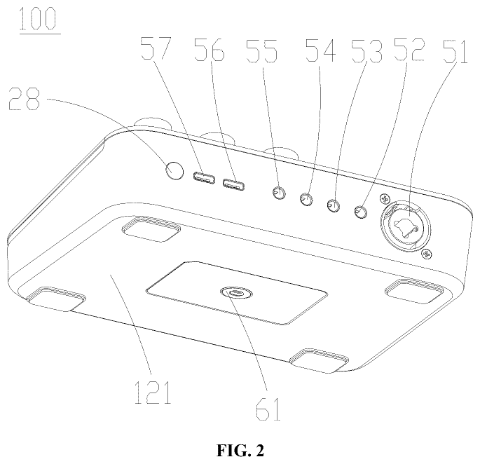

Referring to FIG. 1 and FIG. 2, three-dimensional diagrams of a sound card 100 provided in an embodiment of the present disclosure in two angles. The sound card 100 provided in this embodiment of the present disclosure is configured to be connected to an external device to achieve mutual conversion of sound waves/digital signals. The external device includes, but is not limited to, a microphone, a computer, a tablet, a mobile phone, and another electronic device.

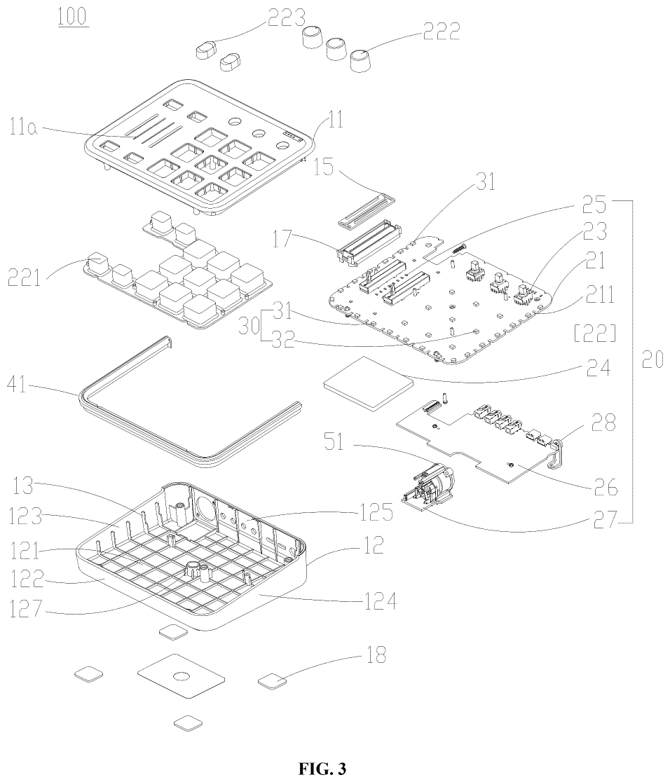

Referring to FIG. 3 to FIG. 5, the sound card 100 includes a shell 10, a control assembly 20, a light emitting assembly 30, and a light guide structure 40. The shell 10 is provided with an accommodating chamber 10a. The control assembly 20 includes a first circuit board 21 arranged in the accommodating chamber 10a. The light emitting assembly 30 is arranged in the accommodating chamber 10a and is electrically connected to the first circuit board 21. The light emitting assembly 30 is configured to emit light. The light guide structure 40 is arranged in the shell 10. The light guide structure 40 is configured to transfer light emitted by the light emitting assembly 30 out of the shell 10.

Compared with the prior art, the sound card 100 provided in the present disclosure uses the light guide structure 40 to transfer the light emitted by the light emitting assembly 30 out of the shell 10, so that a user can observe colorful light, a good lighting atmosphere is created, and a strong visual effect is achieved. Thus, when the user enjoys the auditory effect, a more three-dimensional atmosphere is created in conjunction with the visual effect, and the user experience is enhanced.

Specifically, the light guide structure 40 is arranged at the shell 10, which means that it can be connected to the shell 10, arranged at the shell 1, or arranged in the accommodating chamber 10a in the shell 10. Alternatively, the light guide structure 40 is partially arranged at the shell 10 and partially arranged in the accommodating chamber 10a. The present disclosure will not specifically limit this.

In this embodiment, the shell 10 includes a surface shell 11 and a bottom shell 12. The surface shell 11 and the bottom shell 12 are connected to form the accommodating chamber 10a. Specifically, the bottom shell 12 includes a bottom plate 121 and side plates. The side plates are arranged along a circumferential edge of the bottom plate 121 and are connected to the surface shell 11. The side plates constitute four side surfaces of the shell 10. The side plates of the four side surfaces are defined as a first side plate 122, a second side plate 123, a third side plate 124, and a fourth side plate 125, respectively. The first side plate 122 and the fourth side plate 125 are arranged opposite to each other and are located on front and rear sides of the shell 10. The second side plate 123 and the third side plate 124 are arranged opposite to each other and are located on left and right sides of the shell 10. A height of the fourth side plate 125 is greater than a height of the first side plate 122, so that the sound card 100 has a shape with a lower front part and a higher rear part.

In this embodiment, mounting holes 10b are provided between the side plates and the surface shell 11. The first side plate 122, the second side plate 123, the third side plate 124, and the fourth side plate 125 are integrally formed. Specifically, after the assembling of the side plates and the surface shell 11 is completed, continuous mounting holes 10b communicated to the accommodating chamber 10a are provided between the first side plate 122, the second side plate 123, as well as the third side plate 124, and the surface shell 11. The light guide structure 40 includes first light guide members 41. The first light guide members 41 are arranged in the mounting holes 10b. The first light guide members 41 are arranged on the side surfaces of the shell 10, which does not affect the use of the sound card 100 and can further provide a dazzling lighting effect. It provides a visual effect for a user and enhances the user experience.

In this embodiment, the first light guide members 41 are light-transmittance rubber strips. The first light guide members 41 are arranged in the mounting holes 10b in a penetrating manner, and portions exposed out of the shell 10 respectively resist against the surface shell 11 and the side plates. To better present the lighting effect, the first light guide members 41 have a light filtering property, so that a portion of the light can be filtered out, and the emitted light is selectively transmitted to the outside. Transmitting light waves that a user can accept or likes achieves a better result. In this embodiment, the mounting hole 10b and the exposed portions of the first light guide members 41 are both of U-shaped structures.

In an embodiment, the mounting holes 10b and the first light guide members 41 may only be arranged on one side surface of the shell 10, such as a side surface of a side where the first side plate 122, the second side plate 123, or the third side plate 124 is located. Or, the mounting holes 10b and the first light guide members 41 can be arranged on two side surfaces of the shell 10, such as two side surfaces where the first side plate 122 and the second side plate 123, or the first side plate 122 and the third side plate 124, or the second side plate 123 and the third side plate 124 are located. The present disclosure does not specifically limit this.

In other embodiments, the mounting holes 10b may be arranged between the side plates and the bottom plate 121, or in middle positions of the side plates. In another embodiment, the side plates may also be overall made of a light-transmittance material, and serve as the first light guide members 41 for connecting the bottom plate 121 to the surface shell 11.

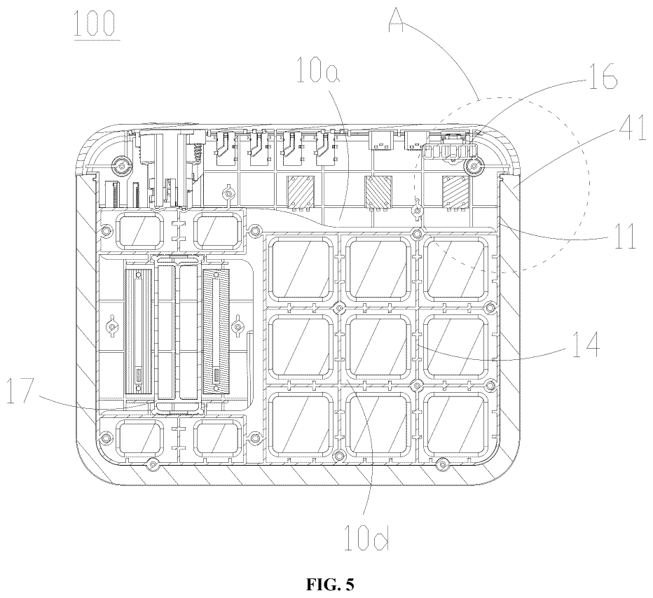

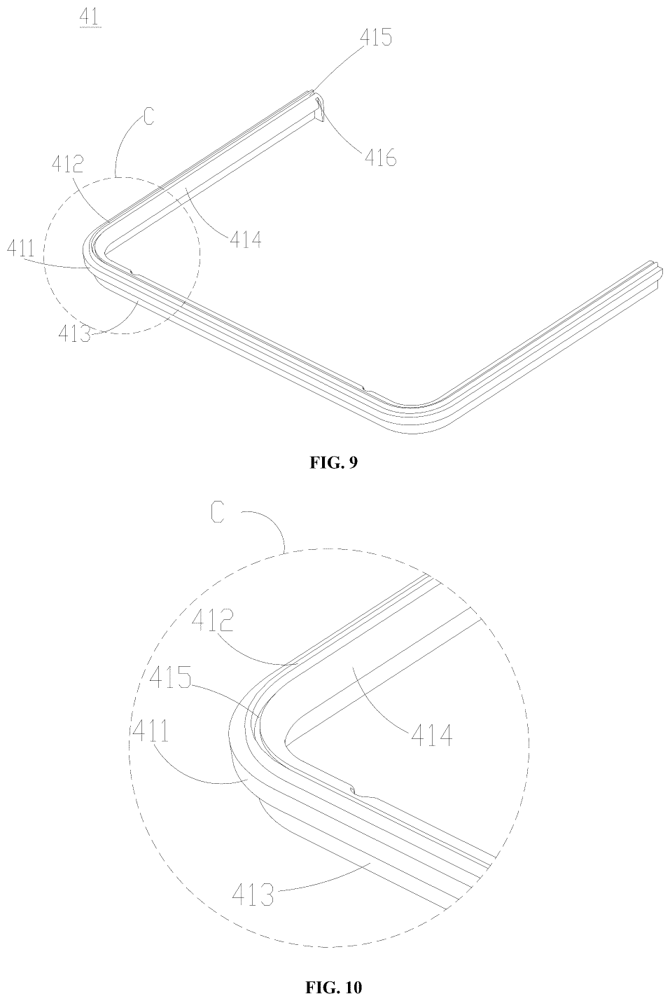

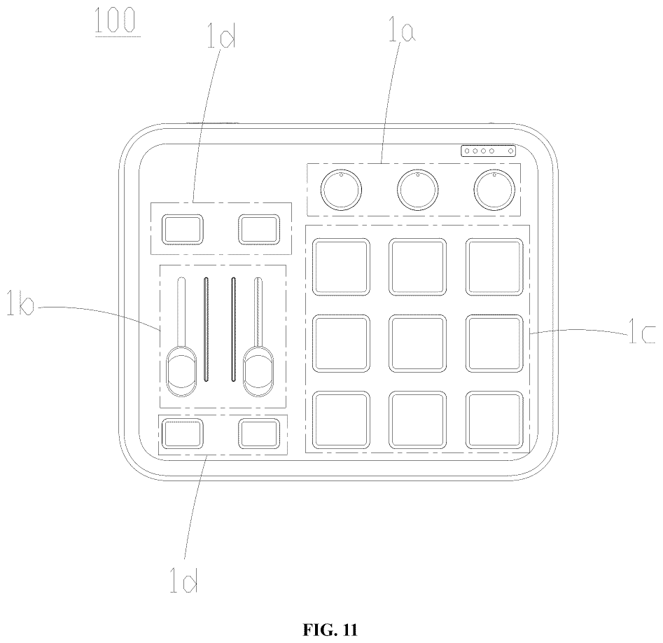

Referring to FIG. 5 to FIG. 10, in this embodiment, each first light guide member 41 includes a main body portion 411, a first clamping portion 412, a limiting portion 413, and a resisting portion 414. The main body portion 411 resists against the surface shell 11 and each side plate, and one side surface is exposed out of the shell 10. Specifically, an exposed outer surface of the main body portion 411 is flush with an outer surface of the side plate, making the appearance of the product more beautiful and neater.

The first clamping portion 412 is arranged on one side of the main body portion 411 and is clamped with a second clamping portion 111 on the surface shell 11, so that the first light guide member 41 and the surface shell 11 are mounted more firmly, and are simple in structure and easy to mount.

The limiting portion 413 is arranged on one side of the main body portion 411 away from the first clamping portion 412, and is adjacent to or resists against the side plate. The resisting portion 414 is arranged on the other side of the main body portion 411 and resists against the surface shell 11. A deformable portion 415 is provided between the resisting portion 414 and the first clamping portion 412. Specifically, the deformable portion 415 is a groove, so that when the first clamping portion 412 is clamped with the second clamping portion 111, there is a deformation space, which can improve the assembling efficiency and avoid damage to parts of the product. The first clamping portion 412, the limiting portion 413, and the resisting portion 414 are all arranged in the accommodating chamber 10a. The limiting portion 413 is adjacent to or resists against the side plate and extends from the main body portion 411 towards he bottom plate 121, so that the first light guide member 41 is limited in the accommodating chamber 10a and prevented from being removed from the mounting hole 10b, thereby ensuring the mounting stability of the first light guide member 41.

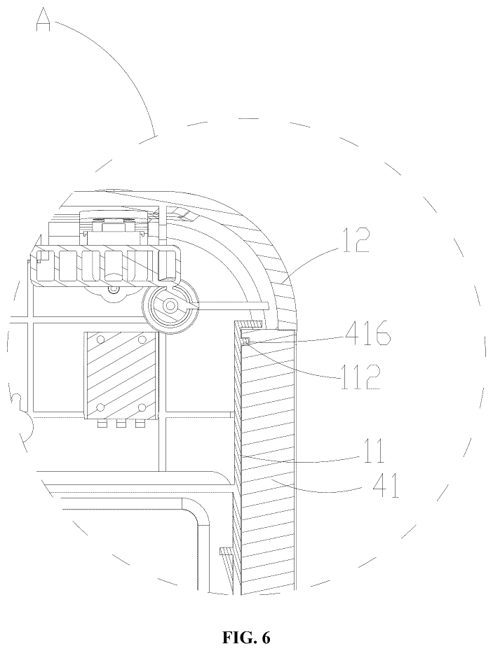

To ensure the stability of connection between the first light guide member 41 and the shell 10, referring to FIG. 6, the first light guide member 41 is further provided with a third clamping portion 416. Specifically, a third clamping portion 416 is arranged on one side of the resisting portion 414 facing the surface shell 11, and a fourth clamping portion 112 is correspondingly arranged on the surface shell 11. The third clamping portion 416 is clamped with the fourth clamping portion 112. In this embodiment, the first clamping portion 412 is a clamping block; the second clamping portion 111 is a clamping slot; the third clamping portion 416 is a clamping slot; and the fourth clamping portion 112 is a clamping block. In other embodiments, the first clamping portion 412 and the fourth clamping portion 112 may also be clamping slots, and the second clamping portion 111 and the third clamping portion 416 may be clamping blocks. The present disclosure does not specifically limit this, as long as they can be clamped with each other.

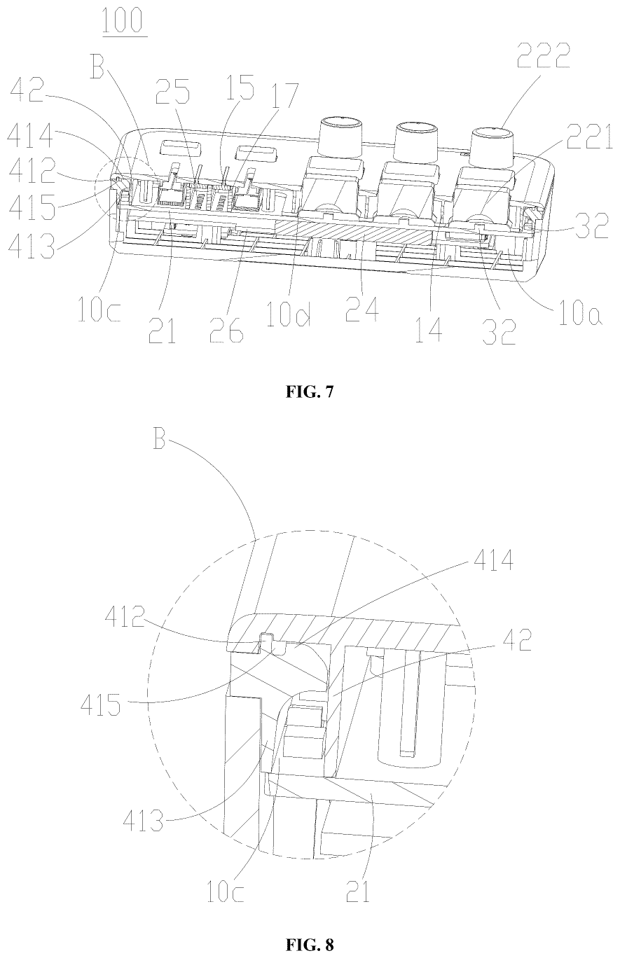

Referring to FIG. 7 and FIG. 8, the resisting portion 414 resists against the surface shell 11, and one side of the main body portion 411 facing the accommodating chamber 10a and one side of the limiting portion 413 facing the accommodating chamber 10a are cambered surfaces. To prevent the light emitted by the light emitting assembly 30 from dissipating to the outside through other positions of the shell 10 and to improve the lighting atmosphere effect, in this embodiment, each light guide structure 40 further includes a first light shielding member 42. The first light shielding member 42 is a baffle plate, which is arranged in the accommodating chamber 10a, is connected to the surface shell 11, and resists against the resisting portion 414 of the first light guide member 41, thereby enclosing a light guide chamber 10c. The light emitted by the light emitting assembly 30 is transferred out of the shell 10 through the first light guide members 41 in the light guide chamber 10c.

Specifically, the light emitting assembly 30 includes first light emitting units 31 electrically connected to the first circuit board 21; the first light emitting units 31 are arranged in the light guide chamber 10c; and the first light emitting units 31 are configured to transfer the emitted light out of the shell 10 through the first light guide members 41. The first light emitting units 31 are arranged in the light guide chamber 10c, which can allow the light emitted by the first light emitting units 31 to be directly transferred out of the shell 10 through the first light guide members 41, thereby reducing the energy loss.

In this embodiment, the first light emitting units 31 are arranged at an edge portion of the first circuit board 21. The first light shielding member 42 resists against the first circuit board 21, and one end, away from the first clamping portion 412, of the limiting portion 413 of each first light guide member 41 resists against the first circuit board 21. The edge portion of the first circuit board 21 is enclosed with the first light shielding member 42 and the first light guide members 41 to form the light guide chamber 10c, and the light emitted by the first light emitting units 31 is transferred out of the shell 10 through the first light guide members 41. Specifically, each first light emitting unit 31 is a light emitting diode (LED) light bead configured to emit light in various colors. In other embodiments, the first light emitting unit 31 may be arranged on one side of the first light shielding member 42 facing the light guide chamber 10c. The present disclosure will impose no limitation on specific arrangement positions of the first light emitting units 31, as long as the light is exported through the first light guide member 41.

Continuing with reference to FIG. 3 and FIG. 7, in this embodiment, a limiting plate 13 is further arranged on the bottom shell 12. A limiting slot 211 is correspondingly provided in the edge portion of the first circuit board 21. A portion of the limiting plate 13 extends into the limiting slot 211, thereby ensuring correct mounting of the first circuit board 21 and avoiding wear or damage to other elements due to movement after mounting. In this embodiment, a size of the first circuit board 21 is roughly equivalent to a size of the bottom plate 121.

In an embodiment, an edge of the first circuit board 21 can also directly resist against the side plates, and the first light shielding member 42, the edge portion of the first circuit board 21, the side plate, and the first light guiding member 41 are enclosed to form a light guide chamber 10c.

In an embodiment, the first light emitting units 31 can also be arranged at an edge portion of the bottom plate 121 adjacent to the side plate, and the first light shielding member 42, the edge portion of the bottom plate 121, the side plates, and the first light guiding members 41 are enclosed to form a light guide chamber 10c. In a changed embodiment of this embodiment, the limiting portion 413 of the first light guide member 41 can also directly resist against the bottom plate 121, so that the first light guide members 41, the bottom plate 121, and the first light shielding member 42 are enclosed to form a light guide chamber 10c.

In another embodiment, the resisting portion 414 of each first light guide member 41 may not resist against the first light shielding member 42. The first light emitting units 31 may be arranged on the surface shell 11. The surface shell 11, the first light shielding member 42, the first light guide members 41, the side plates, and the edge portion of the bottom plate 121 or the first circuit board 21 are enclosed to form a light guide chamber 10c. In a changed embodiment of this embodiment, the limiting portion 413 of each first light guide member 41 can directly resist against the bottom plate 121, so that the surface shell 11, the first light shielding member 42, the first light guide members 41, and the bottom plate 121 are enclosed to form a light guide chamber 10c.

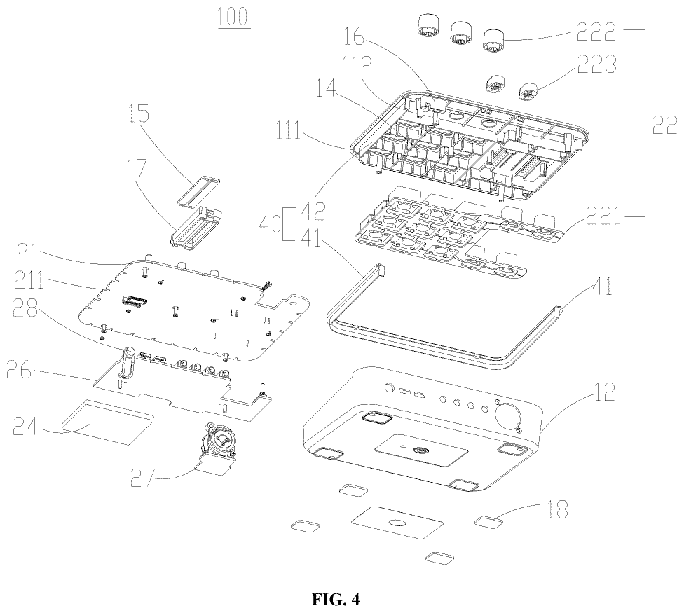

Continuing with reference to FIG. 3 and FIG. 4, in this embodiment, the control assembly 20 further includes function keys. The function keys are arranged at the shell 10 and exposed out of the shell 10, and are electrically connected to the first circuit board 21. The function keys are configured to adjust an increase level of a signal input to the sound card 100 or intensity of a signal output by the sound card 100, or to enable or disable a mute function of the sound card 100. The arrangement of the function keys can better control or adjust the sound card 100, to improve the use efficiency.

Specifically, the function keys 22 include buttons 221, knobs 222, and push keys 223. The function keys are all arranged in holes on the surface shell 11 in a penetrating manner and are exposed out of the shell 10 for user control, such as pressing, rotating, pushing, and pulling. For ease of description and understanding, referring to FIG. 11, in this embodiment, the surface shell 11 is divided into four control regions: a first control region 1a, a second control region 1b, a third control region 1c, and two fourth control regions 1d. The knobs 222 are arranged in the first control region 1a. The first control region 1a is located at a portion of the surface shell 11 close to the fourth side plate 125. The push keys 223 are arranged in the second control region 1b. The second control region 1b is arranged at a portion of the surface shell 11 close to the second side plate 123. Some of the buttons 221 are arranged in the third control region 1c. The third control region 1c is arranged at a portion of the surface shell 11 close to the third side plate 124. Some of the buttons 221 are arranged in the two fourth control regions 1d. The two fourth control regions 1d are arranged at two opposite ends of the third control region 1c, and are respectively located at portions of the surface shell 11 close to the first side plate 122 and the fourth side plate 125. Specifically, heights of the knobs 222 protruding out of the shell 11 are the greatest, followed by the push keys 223 and then the buttons 221. Due to the arrangement of the function keys in the four control regions on the surface shell 11 in this way, the function keys on the surface shell 11 can be staggered, without affecting each other during use, making it convenient for a user to distinguish and use the function keys. For example, when a knob 222 needs to be spun, a user can directly find the highest first control region 1a and operate the knob 222. When a push key 223 needs to be pushed, a user can directly find out the highest push key 223 on the second control region on the left and operate it. When a pressing operation needs to be performed, a user directly finds the third control region 1c or the fourth control region 1d with the lowest function keys.

In this embodiment, three knobs 222, two push keys 223, and 13 buttons 221 are included. Nine buttons 221 are arranged in a nine-grid pattern in the third control region 1c, and the remaining four buttons 221 are arranged in pairs in the two fourth control regions 1d.

For ease of understanding, this embodiment will provide a brief description of the various function keys.

The functions of the two push keys 223 are respectively configured to control a volume of a microphone or accompaniment connected to the sound card 100. For example, one push key controls a volume of an XLR microphone, and the other push key controls a volume of a Bluetooth input, 3.5 mm input, and USB-C downlink accompaniment audio.

One knob 222 is configured to control a gain of a Gain microphone, such as controlling a gain of the XLR microphone. One knob 222 controls Reverb, specifically, controlling the strength of the reverb effect. The reverb effect is turned off when the knob is turned to the most left side. One knob 222 controls a earphone, for example, controlling a volume output by “earphone”and “earpiece”jacks through the knob 222.

The buttons 221 located in the fourth control region 1d has functions of controlling mute of the microphone, mute of the accompaniment, switches of the microphone, on and off of a Bluetooth accompaniment connection function, and the like.

The buttons 221 located in the third control region 1c have functions, including: voice cancel ON/OFF (dodge), monitoring ON/OFF (inside playback ON/OFF), a inflexion mode, a noise reduction function, a glare mode (a light emitting mode of the first light emitting units 31), and four custom function buttons 221, which can customize light brightness, recording, recording clearing, and other functions.

To enhance the glare effect and see the buttons 221 in a dark environment for easy user operation, the buttons 221 has light transmittance. The light emitting assembly 30 includes second light emitting units 32 electrically connected to the first circuit board 21. The second light emitting units 32 are arranged in the accommodating chamber 10a, and the emitted light is transferred out of the shell 10 through the function keys. Specifically, each second light emitting unit 32 is an LED light bead configured to emit light in various colors. The second light emitting units 32 are arranged on one side of the first circuit board 21 facing the buttons 221. Due to a large number of the buttons 221, the number of the second light emitting units 32 corresponds to the number of the button 221, so that each button 221 can transmit light.

Referring to FIG. 3 and FIG. 7, due to a large number of the buttons 221 and a large number of the second light emitting units 32, and adjacent arrangement, to avoid the light emitted by the second light emitting units 32 from affecting the lighting efficiency of other adjacent buttons 221, a second light shielding member 14 is arranged on one side of the surface shell 11 facing the accommodating chamber 10a. The second light shielding member 14 is a baffle plate. The second light shielding member 14 is enclosed with the first circuit board 21 to form a mounting chamber 10d. The second light emitting units 32 are arranged in the mounting chamber 10d, and at least some of the function keys are arranged in the mounting chamber 10d. In this embodiment, partial structures of the buttons 221 are arranged between the second light shielding member 14 and the first circuit board 21, thereby separating the them and avoiding damage to the first circuit board 21 by the second light shielding member 14. By the arrangement of the second light shielding member 14, the light emitted by the second light emitting units 32 can be limited in the mounting chamber 10d where the second light emitting units are located. In this way, the light emitted by the second light emitting units 32 can only be transferred out of the shell 10 through the buttons 221 mounted in the mounting chamber 10d.

Due to the colors of the light emitted by the second light emitting units 32, the buttons 221 can transmit light with different colors, so that the buttons 221 can present different colors when pressed, and can also achieve an indication effect. For example, if the button 221 that controls the mute of the microphone displays a red lighting effect after being pressed, it means that the microphone has been muted. When the button is pressed again to cancel the mute function, the red lighting effect on the button 221 disappears, indicating that the mute function has been canceled. Due to the large number of buttons 221 and relationships between the buttons 221 and corresponding lighting effects, the present disclosure does not list them one by one. In this embodiment, the second light emitting units 32 not only allow the buttons 221 to transmit different lighting effects and enhance the lighting effect of the sound card 100, but also achieve a prompting effect to indicate states of the corresponding functions after the buttons 221 are pressed.

Referring to FIG. 3 and FIG. 4, in this embodiment, the control assembly 20 further includes a first indicator lamp 23 and a battery 24 electrically connected to the first circuit board 21. The first indicator lamp 23 is arranged on the surface shell 11 in a penetrating manner to display a battery level of the battery 24. The battery 24 is arranged in the accommodating chamber 10a. In the sound card 100 provided in this embodiment, there are a plurality of first indicator lamps 23. Five first indicator lamps are taken as an example. When the battery level of the battery 24 is greater than 75%, four first indicator lamps 23 will be turned on. When the battery level of the battery 24 is less than 75% and greater than or equal to 50%, three first indicator lamps 23 will be turned on. When the battery level of the battery 24 is less than 50% and greater than 25%, two first indicator lamps 23 will be turned on. When the battery level of the battery 24 is less than or equal to 25%, one first indicator lamp 23 will be turned on. In other embodiments, other indication forms can be used. For example, the plurality of first indicator lamps 23 are classified into four sections, and a current battery level of the battery 24 is displayed in a columnar shape, representing battery levels of 20%, 40%, 60%, and 80% of the battery 24, respectively. A specific instruction for is not specifically limited in the present disclosure.

To avoid the light emitted by the first indicator lamps 23 from affecting the lighting effects of the surrounding buttons 221, a third light shielding member 16 is further arranged on outer sides of the first indicator lamps 23. The third light shielding member 16 is arranged around the first indicator lamps 23 and resists against the surface shell 11 and the first circuit board 21. The first indicator lamps 23 are arranged on the first circuit board 21 to ensure that the light of the first indicator lamps 23 can only be transmitted to the outside through the surface shell 11.

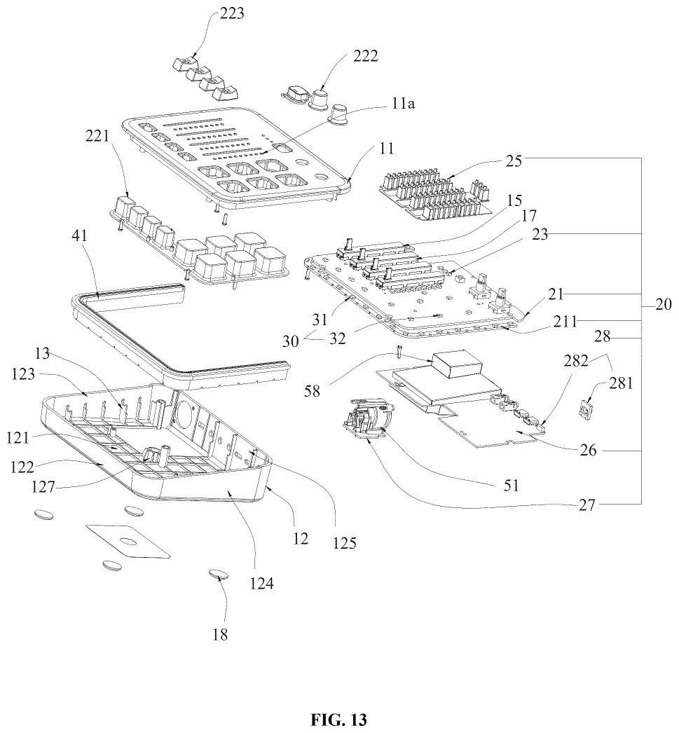

Since the main function of the push keys 223 is to control the volume, in order to more intuitively display the adjustment of the volume by the push keys 223, in this embodiment of the present disclosure, the control assembly 20 further includes a second indicator lamp 25. The second indicator lamp 25 is electrically connected to the first circuit board 21. Specifically, the second indicator lamp 25 is arranged on one side of the first circuit board 21 facing the surface shell 11 and is adjacent to the push keys 223. Specifically, the second indicator lamp 25 is arranged on the first circuit board 21 between the two push keys 223. The second indicator lamp 25 is an LED light bead configured to emit light in various colors. A light-transmittance gap 11a is arranged at a position, corresponding to the second indicator lamp 25, on the surface shell 11, so that the light emitted by the second indicator lamp 25 can be transmitted out of the surface shell 11 through the light-transmittance gap 11a. Alternatively, the second indicator light 25 can be directly exposed from a light hole 11a on the shell corresponding to the transparent gap/single LED bead, as shown in FIG. 13. There are two second indicator lamps 25, which respectively correspond to the two push keys 223; alternatively, there are four second indicator lamps 25, which respectively correspond to four push keys 223, as shown in FIG. 13. The light emitted by the second indicator lamps 25 can indicate a volume size, such as the intensity of a signal of a speaker or a microphone, and whether it is overloaded can be indicated using different colors.

To make the light emitted by the second indicator lamps 25 softer, a second light guide member 15 is arranged in the light-transmittance gap 11a. The second light guide member 15 is a light-transmittance rubber strip that can transmit relatively soft light, so that a user feels more comfortable during observation. Meanwhile, to avoid the light emitted by the second indicator lamps 25 from affecting the surrounding function keys, a fourth light shielding member 17 is further arranged between the surface shell 11 and the first circuit board 21. The fourth light shielding member 17 is arranged around the second indicator lamps 25, and the second light guide member 15 is arranged on one side of the fourth light shielding member 17 facing the surface shell 11, so as to guide the light emitted by the second indicator lamps 25 out of the surface shell 11 through the second light guide member 15.

Referring to FIG. 2, FIG. 3, and FIG. 4, the sound card 100 further includes a port assembly; and the port assembly is electrically connected to the first circuit board 21 and is configured to be connected to the external device. Specifically, the port assembly includes a microphone jack 51, an earpiece jack 52, an accompaniment jack 53, an earphone jack 54, a linear output jack 55, a data jack 56, and a power jack 57. The port assemblies are all arranged in holes of the fourth side plate 125.

The microphone jack 51 is an XLR or 6.35 mm general-purpose microphone jack, supporting inputting of a dynamic microphone with an XLR jack or a 6.35 mm plug.

The earpiece jack 52 supports inputting of mobile phone and gaming earpieces with 3.5 mm TRRS plugs. It has a plugging detection function. This jack automatically blocks an XLR signal input when a four-section earpiece is plugged. If a three-section earphone and other non-earpiece device are plugged, the XLR/6.35 mm microphone jack 51 is still used as an audio input.

The accompaniment jack 53 is configured to be connected to an audio signal input of an external audio device such as a mobile phone, a tablet, a decoder, and a player. It supports an audio playing device such as a mobile phone and an MP3 player to transmit an audio signal to the sound card 100 through an AUX audio cable.

The earphone jack 54 supports both a mobile phone/gaming earpiece (with a TRRS plug) and a regular earpiece (with a TRS plug). After being connected to the sound card 100, it can monitor sounds of various audio channels on the sound card 100.

The linear output jack 55 is a 3.5 mm unidirectional stereo output jack, which is configured to be connected to a speaker and other audio devices.

The data jack 56 is a USB-C data jack configured for uplink and downlink audio signals. The data jack 56 is further configured to serve as a power jack of the sound card 100.

The power jack 57 is a DC power jack 57, which is configured to be connected to an external power supply to supply power to the sound card 100.

In this embodiment, when both the earpiece jack 52 and the earphone jack 54 are used simultaneously, there are sounds output, which improves the applicability of the sound card 100 and enhances the user experience.

In this embodiment, the control assembly 20 further includes a power switch 28. The power switch 28 is arranged in a hole of the fourth side plate 125 and is electrically connected to the first circuit board 21. The power switch 28 is configured to power on and power off the sound card 100.

Referring to FIG. 3 and FIG. 4, to enhance the functionality and control effect of the sound card 100, in this embodiment of the present disclosure, the control assembly 20 further includes a second circuit board 26. The port assembly and the power switch 28 are both electrically connected to the second circuit board 26, and the second circuit board 26 is electrically connected to the first circuit board 21. By the arrangement of the second circuit board 26, the port assembly can be better controlled, thereby providing a better sound effect. Specifically, the second circuit board 26 is arranged between the first circuit board 21 and the bottom plate 121, and is parallel to the first circuit board 21.

To further enhance the sound effect of the microphone connected to the sound card 100, the control assembly 20 is further provided with a third circuit board 27 electrically connected to the microphone jack 51. The third circuit board 27 is arranged between the second circuit board 26 and the bottom plate 121, and is electrically connected to the second circuit board 26. The third circuit board 27 is arranged on one side of the second circuit board 26 away from the first circuit board 21. The three circuit boards are stacked, and a space is reserved between every two circuit boards. By the separate arrangement of the third circuit board 27 for the microphone jack 51, an audio signal input from the microphone to the sound card 100 can be better processed by the third circuit board 27, thereby outputting a better sound effect and enhancing the user experience.

Referring to FIG. 2 and FIG. 3, in this embodiment of the present disclosure, the bottom shell 12 is further provided with a mounting structure. The mounting structure is configured to be detachably connected to a connection structure of the external device, thereby mounting the sound card 100 on the external device, to support the sound card 100. This enlarges the application scope and expands application scenarios.

Specifically, the mounting structure includes a fastener 61 configured to be detachably connected to the external device; the shell 10 is provided with a connector 127; and the fastener 61 is arranged at the connector 127. By the connection between the fastener 61 and the connector 127, the fastener 61 is connected to the shell 10 for easy production and assembling.

For ease of use and cost reduction, the fastener 61 is a screw member having an internal thread; and the connector 127 is a groove or hole provided in the shell 10. Specifically, the connector 127 is arranged on the bottom plate 121. In this embodiment, the fastener 61 can be connected to the connector 127 through adhesive bonding, interference fit, welding, riveting, or screw connection, as long as the fastener 61 can be firmly connected to the connector 127.

In an embodiment, the fastener 61 is a screw hole provided in the connector 127 and having an internal thread. Namely, the fastener 61 can be provided as an internal thread in a groove or hole on the bottom plate 121, and is integrally formed with bottom plate 121. By use of the screw member or screw hole with the internal thread, the product has a simple and practical structure and low cost, is convenient to produce and assemble, and is conveniently connected to, mounted on, and removed from the external device.

It can be understood that to facilitate the use and reduce the cost, the screw hole of the fastener 61 uses a commonly-used conventional standard screw hole and uses a metric or inch thread. Specifically, a diameter of the screw hole is not limited in the present disclosure and can be designed according to a need.

When the connector 127 is set as a groove or hole, to enhance the strength of the bottom plate 121 and avoid the bottom plate 121 from being broken, the connector 127 protrudes slightly towards one side of the bottom plate 121 away from the accommodating chamber 10a, and extends a distance towards one side of the connector 127 facing the accommodating chamber 10a, thereby ensuring the strength of the bottom plate 121 and the strength of the mounted fastener 61. Meanwhile, to further enhance the strength of the bottom plate 121, a reinforcement rib is arranged on the side of the bottom plate 121 facing the accommodating chamber 10a.

In other embodiments, the mounting structure may be a buckle or a buckle slot or another detachable connection structure, as long as it can achieve detachable connection to the external device. The present disclosure will not impose any specific limitation.

To prevent the sound card 100 from shaking or moving during control when the sound card 100 is used, in this embodiment, the bottom plate 121 is further provided with an anti-slip pad 18. The anti-slip pad 18 is specifically a silica gel pad. The silica gel pad is provided with anti-slip lines to increase a friction force between the sound card 100 and an external supporting object such as a desktop, thereby ensuring that shaking or movement of the sound card 100 can be avoided during use.

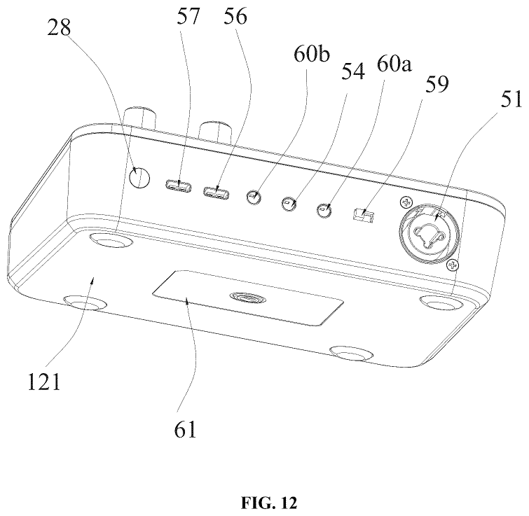

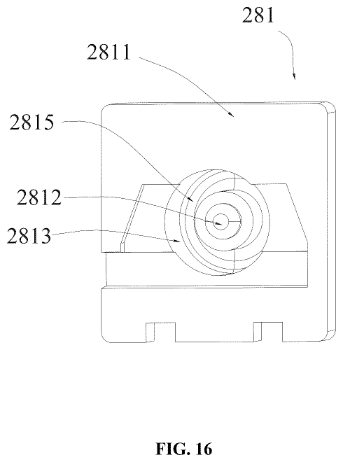

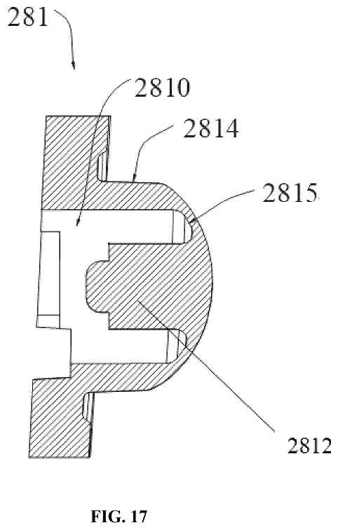

Please refer to FIGS. 12 to 20, which are the accompanying drawings of the second embodiment of the present application.

As shown in FIGS. 12 to 14, the sound card 100 includes a shell 10, a control assembly 20, and a lighting emitting assembly 30. The shell 10 has an accommodating chamber 10a. The control assembly 20 comprises a first circuit board 21 and a plurality of function keys. The first circuit board 21 is mounted in the accommodating chamber 10a, while the plurality of function keys are arranged in the shell 10 with a portion exposed to outside of the shell 10. The plurality of function keys and the lighting emitting assembly 30 are arranged in the accommodating chamber 10a and electrically connected to the first circuit board 21. The light emitting assembly 30 is configured to emit light, and the function keys are designed for controlling or adjusting the sound card, such as adjusting volume, controlling audio signals, and/or switching modes. The light emitted by the lighting assembly can illuminate the function keys, specifically the exposed outer surfaces of the function keys that are outside the shell 10.

Specifically, the structure of the sound card 100 provided above allows the light emitted by the light emitting assembly 30 to be transmitted from the inside of the shell 10 to the outside of the shell 10 through the key buttons, thereby forming a light transmitting effect at the key buttons. This allows users to enjoy auditory effects while also creating a more immersive atmosphere through visual effects, enhancing their user experience. The light emitting effect of the light emitting assembly 30 here can be coordinated with the function keys, such as when pressing the function keys, the RGB lighting effect can be in the form of waves, waves, or water droplet diffusion, and the setting of this function keys can be that the function keys themselves are transparent or semi transparent material, and the light emitted by the light emitting assembly 30 is transmitted through its transparent or semi transparent material. It can also be that there is a gap between the function key and the shell 10, and the light emitted by the light emitting assembly 30 is emitted from the inside of the shell 10 to the outside through the gap. This application prefers that the function key itself is transparent or semi transparent material, so that the light emitted by the light emitting assembly 30 is transmitted more to the outside of the shell 10, resulting in better visual effect and higher user experience.

In present embodiment, as shown in FIG. 12, the plurality of functional keys at least include a power switch 28, as shown in FIGS. 13 to 18. The power switch 28 includes a trigger cover 281 and an electrical connector 282 that is electrically connected to the first circuit board. The electrical connector 282 is positioned in the accommodating chamber 10a of the shell 10. The trigger cover 281 is installed on the shell 10 and corresponds to the electrical connector 282. The trigger cover 281 can trigger the electrical connector 282 by resilient deformation at one end away from the electrical connector 282, so that the sound card can be turned on or off.

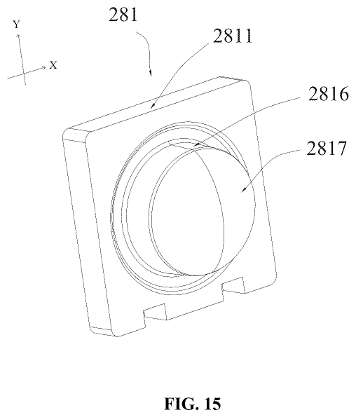

In this embodiment, as shown in FIGS. 15 to 17, the end of the trigger cover 281 away from the electrical connector 282 serves as a pressing end, which has elasticity, the user can trigger the electrical connector 282 by pressing the pressing end of the trigger cover 281 without producing mechanical sound, so that the sound card can be turned on or off, this eliminates the micro electromagnetic interference and conducted vibration caused by the inherent physical friction and bouncing vibration of traditional mechanical switches. Moreover, the pressing end of the trigger cover 281 has elasticity, and frequent use will not cause the switch to get stuck or damaged, increasing the service life of the power switch 28 and improving the user experience. The pressing end of the trigger cover 281 mentioned above is preferably made of silicone as an elastic material, silicone has strong plasticity and resilience, and its hand feel is better, which can improve the user's experience.

In this embodiment, as shown in FIGS. 15 to 17, the trigger cover 281 includes an installation base 2811 for installing a preset power switch on the shell 10 of the sound card, a contact piece 2812 for contacting the electrical connector 282, and an elastic body 2813 for pressing with external force to allow the contact piece 2812 to contact the electrical connector 282. The installation base 2811 is provided with a through hole 2810, when the installation base 2811 is installed on the shell 10, the through hole 2810 is opposite to the electrical connector 282; the elastic body 2813 is fixedly connected to the installation base 2811 and installed at one end of the through hole 2810 away from the electrical connector 282. The contact piece 2812 is fixedly connected to the end of the elastic body 2813 away from the electrical connector 282 and located inside the through hole 2810, which can facilitate user control the contact piece 2812. The contact piece 2812 can trigger the electrical connector 282 by pressing the elastic body 2813 with external force, that is to say, when the elastic body 2813 is pressed with external force, the elastic body 2813 can drive the contact piece 2812 to move until it is pressed against the electrical connector 282. The contact piece 2812 can be made of soft material or hard material, the soft material can be the same as the elastic body 2813, such as silicone material, which is convenient for integrated molding; the hard material can be plastic material, avoiding the use of metal material, which may cause weak electromagnetic interference, and may also produce abnormal noise when in contact with the electrical connection part.

In this embodiment, as shown in FIG. 13 and FIGS. 15 to 17, the elastic body 2813 includes a connecting sleeve 2814 and a deformable ring 2815. The connecting sleeve 2814 is fixedly connected to the end of the installation base 2811 away from the electrical connector 282 and located at the through hole 2810. The deformable ring 2815 is formed in a middle position of the connecting sleeve 2814 and connected to the end of the connecting sleeve 2814 away from the electrical connector 282. One end of the contact piece 2812 is fixedly connected to the connecting sleeve 2814 and located at the inner ring of the deformable ring 2815. The contact piece 2812 can be pressed by external force on the end of the connecting sleeve 2814 away from the electrical connector 282 for triggering of the electrical connector 282. The setting of the deformable ring 2815 makes it smoother for the user to press without any lag, increasing the user's experience. In order to facilitate mold production and improve the user's experience, in this example, it is preferred that the connecting sleeve 2814, the deformable ring 2815, and the contact piece 2812 are integrally formed by silicone injection molding, but not limited to this arrangement. The connecting sleeve 2814, the deformable ring 2815, and the contact piece 2812 can all be made of different materials, but silicone material has stronger plasticity, better resilience, and a better hand feel, which can improve the user's experience.

In this embodiment, as shown in FIG. 13 and FIGS. 15 to 17, the connecting sleeve 2814 includes an installation cylinder 2816 and a force bearing cover 2817. The installation cylinder 2816 is fixedly connected to the end of the installation base 2811 away from the electrical connector 282 and located at the through hole 2810. The extension direction of the installation cylinder 2816 extends away from the electrical connector 282. The force bearing cover 2817 is installed on the end of the installation cylinder 2816 away from the electrical connector 282. The contact piece 2812 is set inside the installation cylinder 2816 and fixedly connected to the force bearing cover 2817, and extends towards the accommodating chamber 10a. The deformable ring 2815 is formed between the contact piece 2812 and the installation cylinders 2816, and the contact piece 2812 can trigger the electrical connection piece 282 by pressing the force bearing cover 2817 with external force. The installation cylinder 2816 extends in the direction away from the electrical connector 282 is for better buffering when the user presses the force bearing cover 2817. Preferably, both the installation cylinder 2816 and the force bearing cover 2817 are made of silicone material and molded together, the installation cylinder 2816 will play a certain connecting role. In other situations, the force bearing cover 2817 is directly connected to the installation base 2811 and is not made of the same material as the installation base 2811, the connection between the force bearing cover 2817 and the installation base 2811 is easily disconnected from the installation base 2811 after multiple pressing activities, i.e, the service life may be reduced without the installation cylinder 2816, because the connection between the installation cylinder 2816 and the installation base 2811 will not be affected by the force bearing cover 2817. Therefore in this embodiment, it is preferred that the installation cylinder 2816 and the force cover 2817 are made of the same material.

In this embodiment, the connecting sleeve 2814, the deformable ring 2815, and the contact piece 2812 are integrally formed by silicone injection molding. The connecting sleeve 2814, the deformable ring 2815, and the contact piece 2812 are integrally formed by silicone injection molding, which is easy to mold out, and the silicone material has stronger plasticity and better resilience. The silicone has a better hand feel and can improve the user's experience.

In this embodiment, the electrical connector 282 is provided with an electrical connection end, and the trigger cover 281 can be pressed by external force to allow the electrical connection end to contract with the electrical connector 282, thereby achieving power on and off.

In this embodiment, the longitudinal section of the force bearing cover 2817 is arc-shaped, as shown in FIG. 15, the Y-axis direction section is taken as the longitudinal section of the force bearing cover 2817, the arc-shaped longitudinal section gives the force bearing cover 2817 resilience, and a deformable ring 2815 can be directly formed between the installation cylinder 2816 and the contact piece, without the need for excessive settings.

Concluded from above, the structure of power switch 28 has been replaced with a trigger cover 281 with elastic pressing end as the power trigger switch, and the best material for the pressing end is silicone, the core advantage of this power trigger switch is to completely eliminate the micro electromagnetic interference (EMI) and conducted vibration caused by the inherent physical friction and bouncing vibration of traditional mechanical switches. Due to the fact that the silicone button itself is only used as a trigger signal and does not directly pass through high current, a clean logic signal is sent to the main control MCU by lightly touching a dedicated low-voltage micro switch or conductive rubber, then, the MCU controls solid-state electronic components such as MOSFETs or relays to complete the actual on/off of the power supply, this “soft switch” design not only completely avoids the arc spark noise generated when mechanical contacts are turned on and off (preventing it from coupling into sensitive analog audio circuits), but also effectively isolates the physical vibration transmission caused by finger pressing with its soft silicone material, providing a cleaner and more stable working environment for high sensitivity components such as preamplifiers and ADCs. Ultimately, it significantly reduces the background noise of the system, improves the overall signal-to-noise ratio (SNR) and audio purity of the sound card.

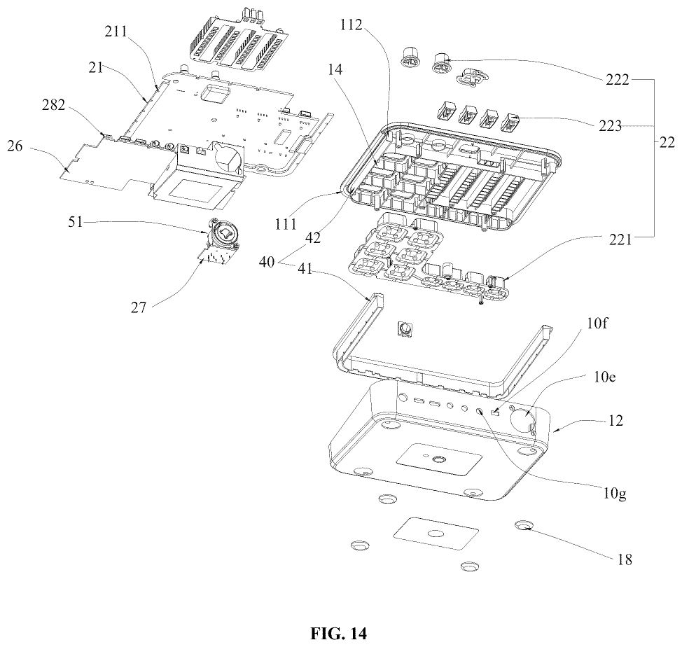

As shown in FIG. 13 and FIG. 14, the sound card further comprises a shielding cover 58, which surrounds to form a shielding cavity. The shielding cover 58 is arranged in the accommodating chamber 10a of the shell 10, and one side wall of the shell 10 is provided with a first placement opening 10e. The shielding cover 58 is provided with a first installation opening 581a, which corresponds to the first placement opening 10e. A microphone jack 51 is installed in the first installation opening 581a, and the interface end of the microphone jack 51 is located at the first placement opening 10e, the other end of the microphone jack 51 opposite to the interface end of the microphone jack 51is set in the shielding cavity. That is to say, there is a shielding cover 58 inside the shell 10 of the sound card, which surrounds to form a shielding cavity, the shielding cover 58 covers the microphone jack 51, and a connection end of the microphone jack 51 for connecting the first circuit board 21 is placed inside the shielding cover 58, in this way, the shielding cover 58 can prevent the sound card light from causing significant signal radiation to the wires near the microphone jack 51 in the circuit inside the shell 10, thereby solving the problem of audio signals being affected by RF interference and affecting signal transmission stability.

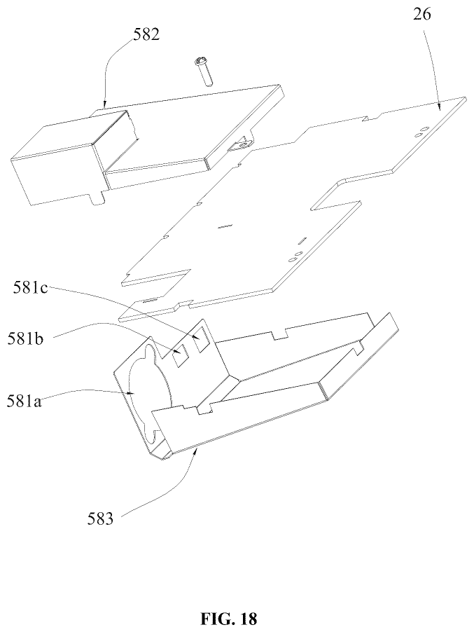

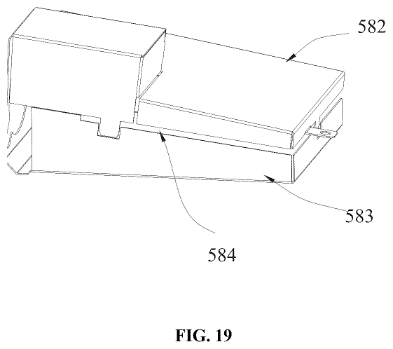

Furthermore, as shown in FIGS. 18 to 19, the shielding cover 58 includes an upper cover 582 and a lower cover 583. The upper cover 582 is mounted on the lower cover 583, and a mounting gap 584 is formed when the upper cover 582 is mounted on the lower cover 583. The first circuit board 21 is partially mounted inside the shielding cavity through the mounting gap 584, this structure mainly indicates that the first circuit board 21 is set between the upper cover 582 and the lower cover 583, a part of the first circuit board 21 is installed inside the shielding cavity, and the connection end of the microphone jack 51 for connecting the first circuit board 21 is inside the shielding cover 58, which blocks the high-frequency RF noise generated by external devices such as mobile phones, Wi-Fi routers, and even computer CPUs/graphics cards from being received and demodulated into noise within the audio range by the high-sensitivity input circuit of the sound card (such as microphone amplifiers). The second circuit board 26 is connected to the first circuit board 21. Compared with the absence of the shielding cover 58, when the mobile phone is placed close to the sound card, a “sizzling . . . ” pulse noise is often heard, which is the RF interference generated by the mobile phone when searching for signals. In other words, this structure is set to prevent them from being received and demodulated into noise within the audio range by the high-sensitivity input circuit of the sound card (such as microphone Extremely low noise, able to capture more sound details, significantly improve signal-to-noise ratio values, and enhance user experience. Signal to Noise Ratio (SNR) is an important indicator for measuring the relationship between useful signals and background noise, it directly affects the way we perceive audio quality, and the larger the SNR value, the better. The above can also be an integrated installation of the upper cover 582 and the lower cover 583, with an installation gap 584 opened on the shielding cover 58 for the installation of the first circuit board 21, however, this structure is not convenient for the electrical connection between the first circuit board 21 and the microphone jack 51. Therefore, in this embodiment, it is preferred to use a combination of the upper cover 582 and the lower cover 583 to install the first circuit board 21.

Furthermore, as shown in FIGS. 12, 14, and 18, the function keys also include a phantom power switch 59. The shielding cover 58 has a first installation opening 581a and a second installation opening 581b on the side wall, the shell 10 also has a second placement opening 10f corresponding to the second installation opening 581b. The phantom power switch 59 is installed inside the second installation opening 581b and its switch end is located at the second placement opening 10f. The phantom power switch 59 is electrically connected to the first circuit board 21. This structure mainly serves as a DC power supply device for the microphone jack 51, and the power supply has voltages including 12V, 24V, and 48V. This application prefers a 48V phantom power supply, which provides stable and safe power supply, with low interference and high fidelity signal transmission, and strong anti-interference ability. The 48v phantom power supply, combined with the shielding cover 58, achieves physical isolation of noise outside the shielding cover 58 and balanced transmission design, effectively reducing signal attenuation during transmission and improving user experience. The function keys also include button 221, knob 222, and pusher 223, which are no different from the embodiments of the present application and will not be repeated here.

As shown in FIG. 12, FIG. 14 and FIG. 18, the port assembly includes a first analog interface 60a, the side wall of the shielding cover 58 with a first installation opening 581a is also provided with a third installation opening 581c, the side wall of the shell 10 corresponding to the third installation opening 581c is also provided with a third placement opening 10g, the first analog interface 60a is installed in the third installation opening 581c, and the interface end of the first analog interface 60a is located at the third placement opening 10g, the first analog interface 60a is electrically connected to the first circuit board 21, then the first analog interface 60a together with the phantom power switch 59 and the microphone jack 51 is also covered by the shielding cover 58, which is mainly “monitoring output” to facilitate real-time sound listening. The first analog interface 60a can be preferably set as 3.5 mm interface, 3.5 mm interface is a universal interface that allows earphones to be inserted without the need for additional adapters. When users first start recording/live streaming, they may only have a regular 3.5 mm earphone and a small microphone, they do not need to buy a professional XLR device to connect to a professional microphone, but simply plug in the 3.5 mm interface to get started and experience it, it is set as a “supplement” for the speaker interface 51, making it convenient for users to use.

Furthermore, as shown in FIG. 18, the lower cover 583 and/or the upper cover 582 are formed by bending copper foil or aluminum foil; copper foil or aluminum foil material can better absorb the sound card light and the signal radiation generated by the electrical signals in the lines of the shell 10, as well as external sound. It can effectively block external electromagnetic interference and achieve better electromagnetic shielding for the shielding cover 58. Copper foil or aluminum foil can be bent into a shape without the need for complex molds and flexible debugging, when modifying the size or shape, only the bending parameters need to be adjusted without the need for re opening the mold, and after molding, the performance is stable and there is no structural damage. Because copper foil or aluminum foil material is thin, occupies less space, and is lightweight, it can achieve the best performance while also making the sound card lightweight as a whole.

Furthermore, when the lower cover 583 is formed by bending copper foil or aluminum foil, the first circuit board 21 is fixed to the lower cover 583 by soldering; when assembling the sound card, the installation sequence of the lower shell is earlier. The specific installation steps are to first fix the lower cover 583 to the first circuit board 21 through its edge soldering, and then bond the whole to the preset position inside the sound card. The above includes but is not limited to soldering for fixed connection, but it is preferred to use soldering, through soldering for fixed connection, the grounding requirements of the lower shell can be met, so that the signal interference absorbed by the shielding cover 58 is conducted out through grounding.

By setting the structure of the shielding cover 58 of the sound card mentioned above, the shielding cover 58 can completely eliminate or greatly reduce the annoying specific noise such as high-frequency radio frequency generated by mobile phones, Wi-Fi routers, and even computer CPUs/graphics cards, as well as the significant signal interference caused by the radiation of electrical signals in the lines of the shell 10 to the wires near the microphone jack 51, significantly improving the signal-to-noise ratio and enhancing the user experience.

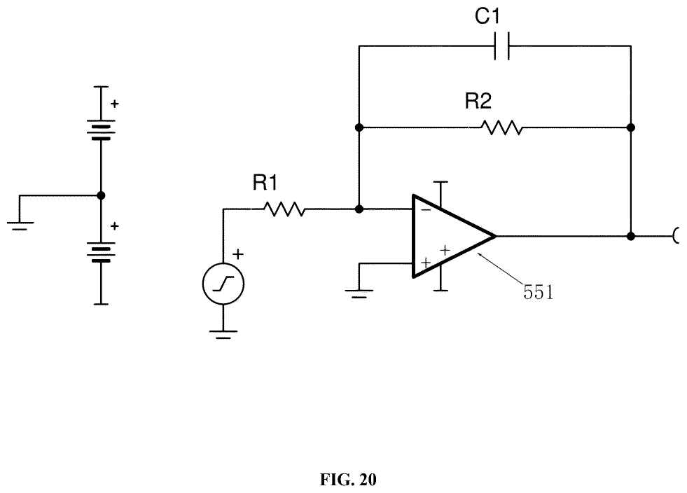

Further, as shown in FIGS. 12 and 20, the port assembly also includes a second analog interface 60b for direct connection to a camera, the second analog interface 60b is also connected with an attenuator, which is used to attenuate the level of the audio signal output by the sound card and then output it to an input end of the camera through the second analog interface 60b. Specifically, the impedance of the attenuator is approximately (400-600) Ω, which forms a voltage division with the external camera, the audio signal output by the second analog interface 60b is a low-level mic in signal, which is suitable for the external camera. In present embodiment, the second analog interface 60b is a TRS or TRRS audio interface with a diameter of 3.5 mm.

Specially, the voltage dividing circuit includes an operational amplifier 551, a first resistance R1, a second resistance R2 and a first capacitance C1, one end of the first resistance R1 is connected to a power supply, the other end of the first resistance R1 is connected to one end of the second resistance R2 and the first input end of the operational amplifier 551 (such as the negative pole), as shown in FIG. 20, Vi is the input end of the operational amplifier 551. One end of the second resistance R2 is connected to the output end of the operational amplifier 551, and the first capacitance C1 and the second resistance R2 are connected in parallel, the second input end (such as the positive pole) of the operational amplifier 551 is grounded, the operational amplifier 551 is further connected to power supply ends Vee and Vcc, the output end of the operational amplifier 551 is connected to the camera by the second analog interface 60b, as shown in FIG. 20, Vo is the output end of the operational amplifier 551, and is used to convert high-level signals into low-level signals; that is to say, the audio signal level output by the sound card is attenuated by the first resistor R1, the second resistor R2, and the operational amplifier 551 voltage division attenuation circuit. This application mainly uses the LMV861 model operational amplifier 551. The port assembly also includes an earphone jack 54, a data jack 56, and a power jack 57, which are consistent with the setting scheme of the first embodiment of the present application and will not be repeated here.

As shown in FIGS. 12 to 14, in order to enhance the functionality and control effect of the sound card 100, in the embodiments of the present application, the port assembly, the power switch 28, the electrical connector 282, and the phantom power switch 59 are all electrically connected to the second circuit board 26 and are all set on the fourth side plate 125. The second circuit board 26 is electrically connected to the first circuit board 21, setting up the second circuit board 26 can better control the port assembly and provide better sound effects. Specifically, the configuration of the second circuit board 26 is not different from the first embodiment of the present application, and will not be repeated here.

The various technical features in the foregoing embodiments may be randomly combined. For concise description, not all possible combinations of the various technical features in the above embodiments are described. However, provided that combinations of these technical features do not conflict with each other, the combinations of the various technical features are considered as falling within the scope of this specification. The foregoing embodiments merely express several implementations of the present disclosure. The descriptions thereof are relatively specific and detailed, but are not understood as limitations on the scope of the present disclosure. A person of ordinary skill in the art can also make several transformations and improvements without departing from the idea of this application. These transformations and improvements fall within the protection scope of this application. Therefore, the protection scope of the patent of this application shall be subject to the appended claims.

What is claimed is:

1. A sound card, configured to be connected to an external device to achieve mutual conversion of sound waves/digital signals, wherein the sound card comprises:
a shell, provided with an accommodating chamber;
a light emitting assembly arranged in the accommodating chamber, and configured to emit light; and
a control assembly comprising a first circuit board and a plurality of function keys, wherein the first circuit board is arranged in the accommodating chamber, the plurality of function keys are mounted in the shell with outer surfaces of the function keys exposed to outside of the shell, the function keys and the lighting assembly are electrically connected to the first circuit board, and the function keys are configured for controlling or adjusting the sound card, light emitted by the lighting emitting assembly illuminates the function keys including the outer surfaces thereof exposed to outside of the shell.

2. The sound card according to claim 1, wherein the function keys include at least a power switch for controlling a power supply of the sound card, the power switch comprises a trigger cover, and an electrical connector positioned in the accommodating chamber and electrically connected to the first circuit board, the trigger cover is mounted on the shell and positioned correspondingly to the electrical connector, by resiliently pressing an end of the trigger cover away from the electrical connector, the electrical connector is triggered to enable or disable the power supply of the sound card.

3. The sound card according to claim 2, wherein the trigger cover comprises an installation base, a contact piece, and an elastic body, the installation base is provided with a through hole, when the installation base is installed on the shell, the through hole corresponds to the electrical connector, the elastic body is fixedly connected to the installation base and installed at the end of the through hole away from the electrical connector, the contact piece is fixedly connected to the end of the elastic body away from the electrical connector and located inside the through hole, the contact piece is capable of triggering the electrical connector by pressing the elastic body with external force.

4. The sound card according to claim 3, wherein the elastic body comprises a connecting sleeve and a deformable ring, the connecting sleeve is fixedly connected to one end of the installation base away from the electrical connector and located at the through hole, the deformable ring is formed in a middle position of the connecting sleeve and connected to one end of the connecting sleeve away from the electrical connector, one end of the contact piece is fixedly connected to the connecting sleeve and located at an inner ring of the deformable ring, the contact piece is capable of triggering the electrical connector by pressing the end of the connecting sleeve away from the electrical connector with external force.

5. The sound card according to claim 4, wherein the connecting sleeve comprises an installation cylinder and a force bearing cover, the installation cylinder is fixedly connected to one end of the installation base away from the electrical connector and located at the through hole, the installation cylinder extends in a direction away from the electrical connector, the force bearing cover is installed on one end of the installation cylinder away from the electrical connector, the contact piece is fixedly connected to the force bearing cover, located inside the installation cylinder, and extends towards the accommodating chamber, the deformable ring is formed between the contact piece and the installation cylinder, the contact piece is capable of triggering the electrical connector by pressing the force bearing cover with external force.

6. The sound card according to claim 4, wherein the connecting sleeve, deformable ring, and contact piece are integrally formed by silicone injection molding.

7. The sound card according to claim 1, further comprising a shielding cover and a port assembly, the port assembly comprises a microphone jack configured for audio signal input, the shielding cover enclosing a shielding cavity, the shielding cover being arranged within the accommodating chamber, a first placement opening being provided on one side wall of the shell, a first installation opening being provided on the shielding cover, the first installation opening corresponding to the first placement opening, the microphone jack being installed within the first installation opening and an interface end of the microphone jack being located at the first placement opening, and the other end of the microphone jack opposite to the interface end of the microphone being arranged within the shielding cavity

8. The sound card according to claim 7, wherein the shielding cover comprises an upper cover shell and a lower cover shell, the upper cover shell is installed on the lower cover shell, and a mounting gap is formed when the upper cover shell is installed on the lower cover shell, the first circuit board is installed inside the shielding cavity through the mounting gap.

9. The sound card according to claim 7, wherein the function keys include a phantom power switch, wherein the shielding cover is provided with a second installation opening on a side wall of the first installation opening, and the shell is provided with a second placement opening corresponding to the second installation opening, the phantom power switch is installed inside the second installation opening, and a switch end of the phantom power switch is located at the second placement opening, the phantom power switch is electrically connected to the first circuit board;
the port assembly further includes a first analog interface, the side wall of the shielding cover where the first installation opening is located, is further provided with a third installation opening, the side wall of the shell corresponding to the third installation opening is also provided with a third placement opening, the first analog interface is installed in the third installation opening, an interface end of the first analog interface is located at the third placement opening, and the first analog interface is electrically connected to the first circuit board.

10. The sound card according to claim 8, wherein the lower cover and/or the upper cover are formed by bending copper foil or aluminum foil; and when the lower cover is formed by bending copper foil or aluminum foil, the first circuit board is fixed to the lower cover by soldering.

11. The sound card according to claim 1, further comprising a port assembly, the port assembly includes a second analog interface used to connect an external camera for transmitting processed audio signals to the camera.

12. The sound card according to claim 11, wherein the second analog interface is further connected to an attenuator, the attenuator is used to attenuate the audio signal level output by the sound card, and then output to an input end of the camera via the second analog interface.

13. The sound card according to claim 12, wherein the attenuator comprises an operational amplifier, a first resistance and a second resistance, one end of the first resistance is connected to a power supply, the other end of the first resistance is connected to one end of the second resistance and a first input end of the operational amplifier, the other end of the second resistance is connected to an output end of the operational amplifier, the second input end of the operational amplifier is grounded, and the output end of the operational amplifier is further connected to the camera through the second analog interface.

14. The sound card according to claim 13, wherein the attenuator further comprises a first capacitor, the first capacitor is connected in parallel with the second resistor.

15. The sound card according to claim 11, wherein the port assembly further comprises an earphone jack electrically connected to the first circuit board and used for plugging in an external device for listening.

16. The sound card according to claim 15, wherein the earphone jack is an analog interface and is arranged adjacent to the second analog interface.

17. The sound card according to claim 7, wherein the control assembly further comprises a second circuit board, which is electrically connected to the first circuit board and stacked with the first circuit board, the port assembly is located on the second circuit board.

18. The sound card according to claim 1, further comprising a light guide structure arranged on the shell, the light guide structure is configured to transfer the light emitted by the light emitting assembly out of the shell, wherein the light guide structure comprises first light guide members; the first light guide members are arranged on the shell; and the first light guide members are located on two or more side surfaces of the shell.

19. The sound card according to claim 18, wherein a side surface of the shell is provided with a mounting hole communicated to the accommodating chamber; each first light guide member comprises a main body portion and a first clamping portion connected to the main body portion; the main body portion is arranged in the mounting hole; a portion of the main body portion is exposed out of the shell; the shell is provided with a second clamping portion on one side facing the accommodating chamber; and the first clamping portion is clamped with the second clamping portion.

20. The sound card according to claim 1, wherein the function keys have light transmittance.
